(19) United States
(12) Patent Application Publication
(10) Pub. No.: US 2025/0141219 A1
(43) Pub. Date: May 1, 2025

(54) ELECTROSTATIC DISCHARGE PROTECTION

(71) Applicant: Infineon Technologies AG, Neubiberg (DE)

(72) Inventors: Mirko Scholz, Ottobrunn (DE); Steffen Schumann, Biebelsheim (DE); Gernot Langguth, Oberhaching (DE); Adrien Benoit Ille, Unterhaching (DE)

(21) Appl. No.: 18/931,784

(22) Filed: Oct. 30, 2024

(30) Foreign Application Priority Data
Oct. 31, 2023 (DE) 102023210805.4

(51) Int. Cl. H02H 9/04

(52) U.S. Cl. CPC H02H 9/044

(57) ABSTRACT

In accordance with an embodiment, a device includes: a first supply rail; a second supply rail; an input/output terminal; an electrostatic discharge protection device comprising at least two stacked transistors coupled between the input/output terminal and a first one of the first supply rail or the second supply rail; and a trigger circuit coupled to the first supply rail and the second supply rail and configured to: detect an electrostatic discharge event at the input/output terminal based on a voltage of the first supply rail or a voltage of the second supply rail, and switch on the electrostatic discharge protection device in response to detecting the electrostatic discharge event.

This application claims the benefit of German Application No. 102023210805.4, filed on Oct. 31, 2023, which application is hereby incorporated herein by reference.

### TECHNICAL FIELD

The present application relates to devices for electrostatic discharge protection.

### BACKGROUND

Semiconductor integrated circuits are generally sensitive to electrostatic discharge (ESD) events where a high charge is applied to a terminal of the integrated circuit. Such a charge may be for example applied when a human being touches the terminal of the circuit and may cause voltages of the order of several hundred volts and above to be present, which are considerably higher than voltages the circuit is designed for and which therefore may damage the circuit.

Accordingly, terminals of semiconductor devices are protected using ESD protection circuits. A common approach to protect an input/output (IO) terminal is to couple the IO terminal to supply rails providing supply voltages via ESD protection diodes, which are designed such that they are non-conducting during normal operation, e.g. voltages occurring during normal operation of the circuit do not exceed a forward voltage of the diodes. In case of an ESD event, at least one of the diodes becomes conducting, thus deviating the charge and preventing a high voltage drop over a core circuit of the device, i.e. a circuit performing the actual functions of the device.

However, a remaining charge or voltage drop may still have the potential to damage the device, in particular with increasing miniaturization of semiconductor structures and lowering of supply voltages, which makes the devices more sensitive to overvoltages.

### SUMMARY

According to an embodiment, a device is provided, comprising: a first supply rail, a second supply rail, an input/output terminal, and an electrostatic discharge protection device comprising at least two stacked transistors coupled between the input/output terminal and one of the first supply rail and the second supply rail.

The device further comprises a trigger circuit coupled to the first supply rail and the second supply rail. The trigger circuit is configured to detect an electrostatic discharge event at the input/output terminal based on at least one of a voltage at the first supply rail and a voltage at the second supply rail and to switch the electrostatic discharge protection device on in response to detecting the electrostatic discharge event.

According to another embodiment, a device is provided, comprising: a first supply rail, a second supply rail, an input/output terminal, and an electrostatic discharge protection switch coupled between the input/output terminal and one of the first supply rail and the second supply rail.

The device further comprises a detection circuit coupled to the first supply rail and the second supply rail and configured to detect an electrostatic discharge event at the input/output terminal based on at least one of a voltage at the first supply rail and a voltage at the second supply rail and to generate a detection signal in response to detecting the electrostatic discharge event. The device further comprises an amplifier circuit configured to amplify the detection circuit to generate a control signal for the electrostatic discharge protection switch.

The above summary gives merely a brief overview over some embodiments and is not to be construed as limiting, as other embodiments may include other features than the ones listed above.

### BRIEF DESCRIPTION OF THE DRAWINGS

FIG. 1 is a diagram illustrating a device according to an embodiment;

FIG. 2 is a diagram illustrating a device according to an embodiment;

FIG. 3 is a circuit diagram illustrating a device according to an embodiment;

FIGS. 4A-4E are diagrams illustrating biasing circuits usable in various embodiments;

FIG. 5 is a circuit diagram illustrating a device according to an embodiment; and

FIG. 6 is a circuit diagram illustrating a device according to a further embodiment.

### DETAILED DESCRIPTION OF ILLUSTRATIVE EMBODIMENTS

In the following various embodiments will be described in detail referring to the attached drawings. These embodiments are given by way of example only and are not to be construed as limiting in any way.

In some of the embodiments described in the following, transistors are used. While specific types of transistors may be shown in the drawings, for example metal oxide semiconductor field effect transistors (MOSFETs), in other embodiments other types of transistors, for example bipolar junction transistors (BJTs) or insulated gate bipolar transistors (IGBTs) may be used. In some embodiments, stacked transistors may be used. Stacked transistors refer to one or more transistors with their load paths coupled in series. In case of field effect transistors, the term “load path” refers from the path between source and drain, and in case of BJTs or IGBTs the term “load path” refers to the path between collector and emitter.

Any connections or couplings described herein are shown the drawings refer to electrical connections or couplings unless noted otherwise. Such connections or couplings may be modified, for example by adding elements or removing elements, as long as the function of connection or coupling, for example to provide a voltage or current, to transmit a signal, to provide a control etc. is maintained. In this sense, the couplings are to be seen as functional couplings, i.e. the elements are coupled electrically to provide the functions described herein.

Features from different embodiments may be combined to form further embodiments. Variations and modifications described with respect to one of the embodiments may also be applied to other embodiments and will therefore not be described repeatedly.

Throughout the figures, the same reference numerals are used to designate corresponding or equivalent elements.

Embodiments described herein relate to devices which include a secondary electrostatic discharge (ESD) protection. Such a secondary ESD protection may be combined with any primary ESD protection. In some embodiments, the primary ESD protection is illustrated as including two diodes, but any other primary ESD protection, for example using transistors coupled as diodes or other ESD protection elements, may also be used.

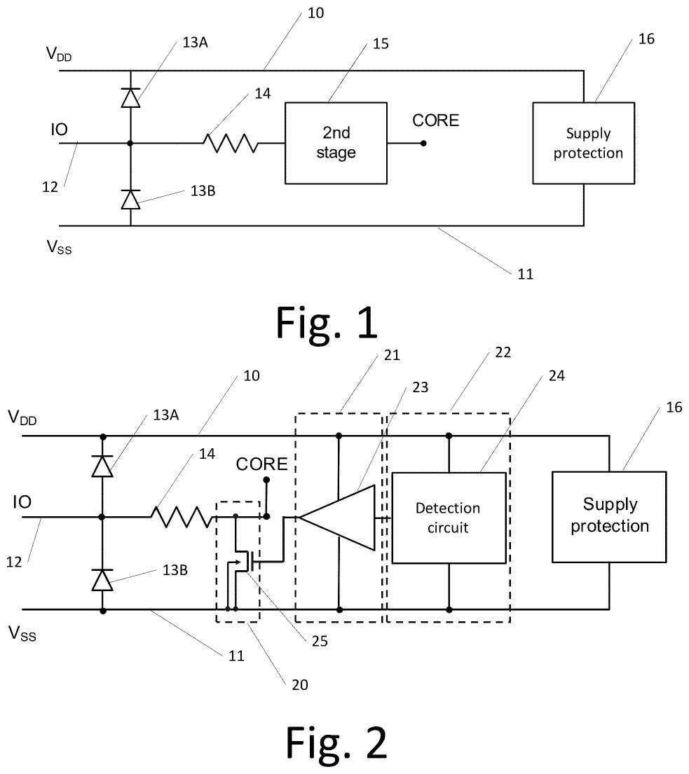

FIG. 1 illustrates a block diagram of a device according to an embodiment.

The embodiment of FIG. 1 includes a first supply rail supplying a first supply voltage V_{DD} and a second supply rail 11 supplying a second supply voltage V_{SS}. While V_{DD} and V_{SS} are shown as examples for supply voltages, in other embodiments other supply voltages may be provided, for example V_{CC} and V_{EE} in a bipolar logic or a positive voltage and ground.

Furthermore, an input/output (IO) terminal 12 is provided. While a single IO terminal 12 is shown, devices may include a plurality of IO terminals, which may be protected from ESD events as described herein. In other embodiments, one or more of a plurality of IO terminals may be protected as described herein, and other IO terminals may be provided without protection or with different ESD protection.

Supply rails 10, 11 supply any core circuit of the device, simply designated with the word “CORE” in FIG. 1. The core circuit is the circuit that performs the function the device is intended for, for example logic functions, control functions, calculation functions, etc. As the present application relates to electrostatic discharge protection, the core circuit will not be specified further, and embodiments described herein may be used to protect any core circuit from electrostatic discharge events. IO terminal 12 may be used to provide input signals to the core circuit, to provide output signals from the core circuit to the outside world or both. In this respect, the term “IO terminal” includes also cases where a terminal is only used for inputting signals (pure input terminal) are only used for outputting signals (pure output terminal).

Supply rails 10, 11 are protected by a supply protection 16, which may be implemented in any conventional manner for example to reduce high voltages between the supply rails 10, 11 due to an electrostatic discharge event. As the present application focuses on the protection of IO terminals like IO terminal 12, the supply protection will not be described in any particular detail and may or may not be provided.

A primary ESD protection stage for IO terminal 12 is provided by two diodes 13A, 13B. Diode 13A is coupled between IO terminal 12 and first supply rail 10 as shown, and diode 13B is provided between IO terminal 12 and second supply rail 11 as shown. Depending on a polarity of an electrostatic discharge event at IO terminal 12 compared to supply rails 10, 11, diode 13A and/or 13B becomes conducting, thus deviating the ESD voltage. During normal operation (outside ESD events), diodes 13A, 13B are essentially non-conducting, such that the device may operate as intended. As in some applications such a primary ESD protection may not always be sufficient, in addition to the above-mentioned diodes or similar devices serving as primary ESD protection stage, a secondary protection stage as described below is used to further minimize the risk of damage to the device.

IO terminal 12 is coupled to the core circuit via a resistor 14 and a secondary ESD protection stage 15. Specific embodiments of secondary ESD protection stage 15 will be described in the following. Resistor 14 limits the current flowing to the core circuit in case of an ESD event. Other or additional current limiting elements, for example a capacitor, may be used as well.

As will be described further below in more detail, in embodiments described herein secondary ESD protection stage 15 detects an ESD event at input/output terminal 12 based on a voltage at first supply rail 10 and/or second supply rail 11. When an ESD event happens and diode 13A or 13B becomes conducting, this also modifies the voltage at the respective supply rail 10 or 11, which may be detected by secondary ESD protection stage 15 to trigger an electrostatic discharge protection device, e.g. switch, as will be described below. By providing the detection circuit between the supply rails 10, 11, in some embodiments leakages at the IO terminal 12 may be reduced.

FIG. 2 is a diagram illustrating a device according to a further embodiment. Here, the secondary ESD protection stage 15 of FIG. 2 includes an electrostatic discharge protection device 20 including a transistor switch 25. The load path of transistor switch 25 is coupled between IO terminal 12, in particular a node between resistor 14 and the core circuit, and supply rail 11. Alternatively or additionally, a transistor switch coupling IO terminal 12, in particular the node between resistor 14 and the core circuit, to first supply rail 10 may be provided.

Furthermore, the secondary ESD protection stage of FIG. 2 comprises a detection circuit 22, which is represented by a block 24 in FIG. 2, which detects an ESD event based on voltages at first and second supply rails 10, 11. As explained above, when an ESD event at IO terminal 12 occurs and is deviated to at least one of supply rails 10, 11 via diodes 13A, 13B, the voltage at first supply rail 10 and/or second supply rail 11 changes, which may be detected by block 24. Possible circuit implementations of block 24 will be described further below. Possible implementations of block 24 include a voltage divider circuit or an RC (resistor-capacitor) filter circuit.

Block 24 generates a detection signal, which is provided to an amplifier circuit 21, represented by an amplifier 23 in FIG. 2. Amplifier circuit 21 provides a control signal for electrostatic discharge protection device 20 based on the detection signal. In the example including the transistor switch 25, the control signal is provided to the gate terminal of the transistor. Detection circuit 22 and amplifier circuit 21 together are also referred to as trigger circuit herein.

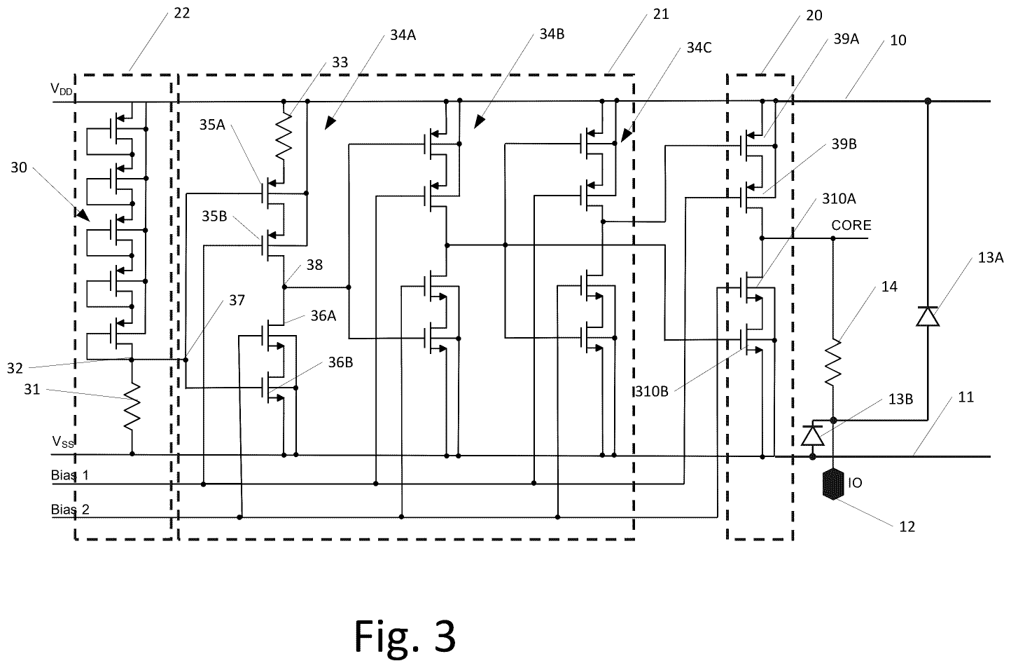

FIG. 3 is a circuit diagram of a device according to an embodiment, which includes implementation examples of ESD protection device 20, amplifier circuit 21 and detection circuit 22. Detection circuit 22 in the example of FIG. 3 comprises a voltage divider circuit including a chain of diode-coupled transistors 30 and a resistor 31 coupled in series between first supply rail 10 and second supply rail 11. Detection circuit 22 generates a detection signal at a node 32. The number and forward voltages of diode-coupled transistors 30 and a resistance value of resistor 31 are selected such that during normal operation, essentially no leakage current occurs via detection circuit 22, and a voltage at node 32 is such that ESD protection circuit 20 is not triggered. When the voltages at first supply rail 10 and/or second supply rail 11 vary due to an ESD event at IO terminal 12, which is deviated via diode 13A and/or 13B, a voltage at node 32 reflects this change ultimately triggering ESD protection device 20. Instead of diode-coupled transistors 30, other kinds of diodes like pn diodes or pin diodes may be used.

Amplifier circuit 21 in the embodiment of FIG. 3 comprises three inverter stages 34A-34C. The number of three inverter stages is merely an example, and more or less inverter stages may also be provided. First inverter stage 34A will be described in more detail in the following. Second inverter stage 34B and third inverter stage 34C are essentially provided similar to first inverter stage 34A, with the only difference being that a resistor 33 is provided in first inverter stage 34A and omitted in second and third inverter stages 34B and 34C.

Inverter stage 34A comprises an input node 37, which is coupled to node 32 as shown, and an output node 38, which is coupled to a corresponding input node of inverter stage 34B.

Inverter stage 34A furthermore comprises a pair of stacked PMOS transistors 35A, 35B and a pair of stacked NMOS transistors 36A, 36B. The use of stacked transistors may provide a higher voltage tolerance than the use of single transistors. In this way, amplifier circuit 21 may be implemented in a comparatively low voltage technology and still handle the required voltages.

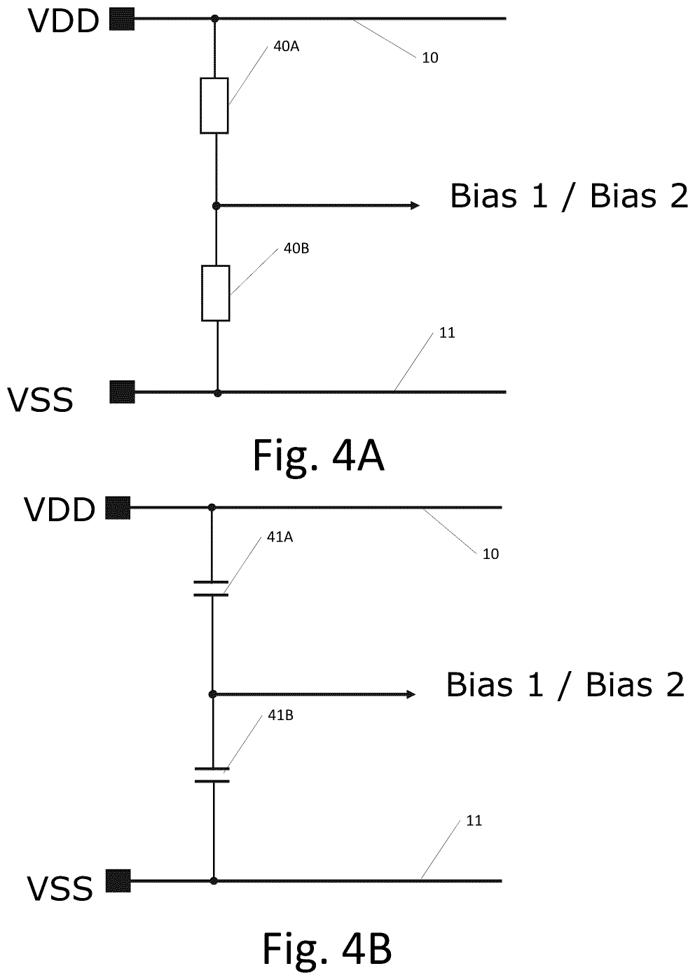

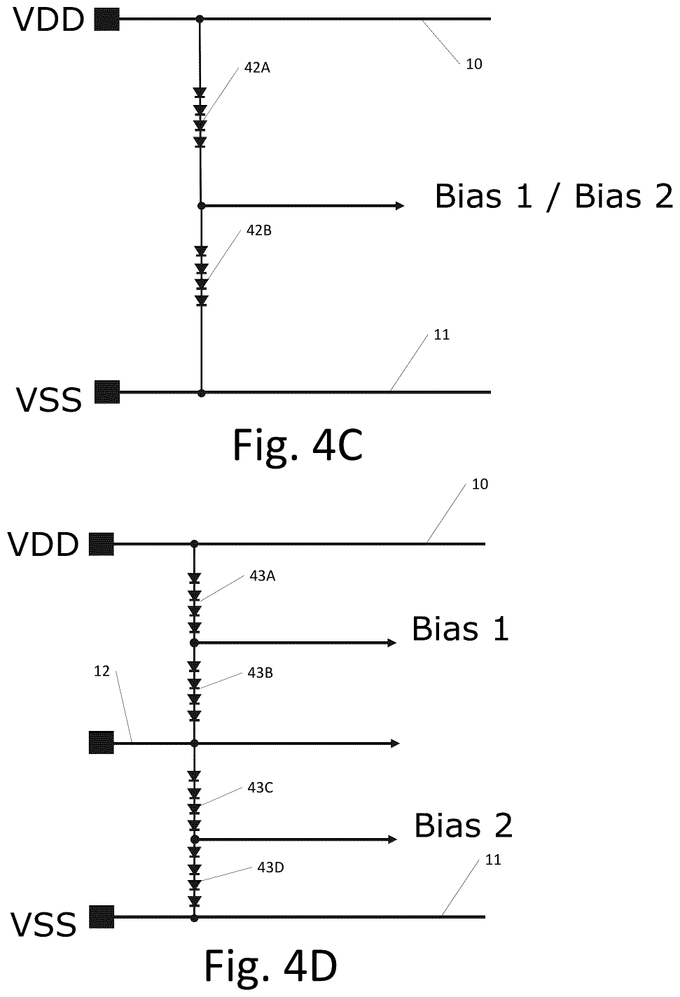

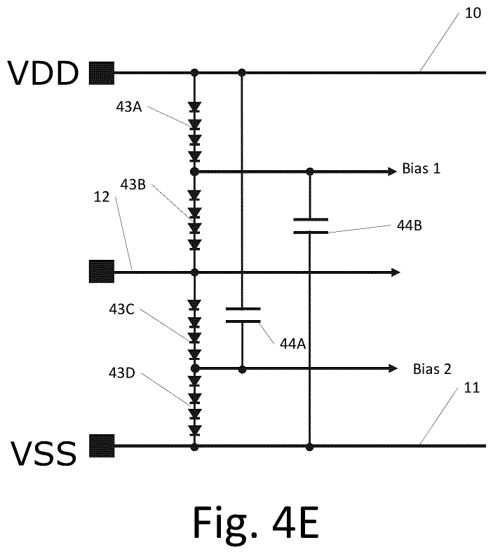

PMOS transistor 35A and NMOS transistor 36B are coupled to input node 37 as shown. The load paths of PMOS transistors 35A, 35B are coupled between output node 38 and a first end of resistor 33, and a second end of resistor 33 is coupled to first supply rail 10. Resistor 33 may have a resistance value in the Kiloohm range and may be omitted in other embodiments. The load paths of NMOS transistors 36A, 36B are coupled between output node 38 and second supply rail 11. A gate terminal of PMOS transistor 35B is biased by a voltage Bias 1, and a gate of NMOS transistor 36A is biased by a voltage Bias 2. Generation of bias voltages Bias 1 and Bias 2 is explained further below with reference to FIGS. 4A to 4E. Generally, the bias voltages are selected such that in normal operation, the transistors are off to prevent leakage currents, while when either transistor 35A or transistor 36B is switched on by the detection signal output by detection circuit 22, through the respective source voltages provided in this way to transistor 35B or 36A, respectively, also transistor 35B is switched on when transistor 35A is switched on, or also transistor 36A is switched on when transistor 36B is switched on.

Apart from the omission of resistor 33 as mentioned above, second inverter stage 34B and third inverter stage 34C are configured as first inverter stage 34A, with stacked transistors, of which one of each pair (PMOS or NMOS) is coupled to the respective input node and the other one is coupled to the respective bias voltage Bias 1 or Bias 2. An input node of second stage 34B is coupled with output node 38, and an input node of third stage 34C is coupled to an output node of second stage 34B as shown, such that the first, second and third stage are coupled in series.

Therefore, although only one transistor of each stacked pair is coupled to the respective input node 37, the stages operates as a usual inverter.

ESD protection device 20 comprises a pair of PMOS transistors 39A, 39B, and a pair of stacked NMOS transistors 310A, 310B. Similar to the inverter stages 34A-34C, PMOS transistor 39B is biased by Bias 1, and NMOS transistor 310A is biased by Bias 2. A gate terminal of PMOS transistor 39A is coupled to the output node of inverter stage 34C, and a gate terminal of NMOS transistor 310B is coupled to the output node of inverter stage 34B, such that the signal applied to the gate terminal of PMOS transistor 39A is the inverse (separated by one inverter stage) of the signal applied to the gate terminal of NMOS transistor 310B. Therefore, in case of an ESD event, transistors 39A and 310B are switched on, which then through the biasing (gate-source voltages which then are established) also switches on transistors 39B, 310A, such that the charge is further deviated from IO terminal 12 to first and second supply rails 10, 11.

The PMOS transistors of the inverter stages 34A to 34C and of electrostatic discharge protection device 20 are biased by VDD at their body terminals, and the NMOS transistors are biased by VSS at their body terminals, as shown. Note that “VDD” or “VSS” in case of an ESD event are the voltages as modified by the ESD pulse or, in case the device is turned off (without power supply), voltages provided by the ESD pulse alone, which then supplies the ESD protection circuit.

Various possibilities for generating the bias voltages Bias 1 and Bias 2 of FIG. 3 will now be discussed with reference to FIGS. 4A-4E.

FIG. 4A is a first example where the voltages Bias 1 and Bias 2 are generated by a resistive divider comprising resistors 40A, 40B between the first and second supply rails 10, 11 as shown. Resistors 40A and 40B may be high ohmic, for example exceeding 100 kΩ, to reduce leakage currents.

In this case, the voltages Bias 1 and Bias 2 are equal and approximately halfway between VDD and VSS. If VSS is taken as zero level, therefore the voltages Bias 1 and Bias 2 are approximately VDD/2. It should be noted that this need not be exact, such that resistors 40A and 40B need not be exactly equal. For example, variations of +/−10% around VDD/2 may be acceptable.

FIG. 4B shows a further possibility for biasing, where instead of a resistive voltage divider as in FIG. 4A a capacitive voltage divider using capacitors 41A, 41B are shown. The use of capacitors may reduce leakage currents between VDD and VSS. In embodiments, capacitance values of capacitors 41A, 41B are equal (again with some tolerances allowable), such that Bias 1 and Bias 2 are again equal and halfway between VDD and VSS, i.e. at about VDD/2 (e.g. with tolerances of +/−10%) if VSS is used as zero-point of the voltage scale.

In FIG. 4C, a voltage divider is formed by two diode chains 42A, 42B. The number of diodes may be selected based on the voltage VDD with respect to VSS and leakage requirements, more diodes leading to reduced leakages. Also here, the two diode chains 42A, 42B may be essentially equal, such that Bias 1 and Bias 2 are again about VDD/2, with corresponding variations, for example about +/−10%, allowable.

In the above implementations of FIGS. 4A-4C, Bias 1 and Bias 2 are equal. In this case, in FIG. 3 a single line for biasing may be used, i.e. no separate lines for Bias 1 and Bias 2 are needed. Now, referring to FIGS. 4D and 4E, implementations will be shown where Bias 1 and Bias 2 are different.

In FIG. 4D, Bias 1 is generated by a first diode chain based voltage divider including diode chains 43A, 43B between first supply rail 10 and IO terminal 12, and Bias 2 is generated by a second diode chain based voltage divider including diode chains 43C, 43D between IO terminal 12 and second supply rail 11. Diode chains 43A, 43B may be essentially equal, and diode chains 43C, 43D may be essentially equal. In some embodiments, all four diode chains 43A-43D may be essentially equal. Instead of diode chain based voltage dividers, also resistive voltage dividers as in FIG. 4A or capacitive voltage dividers as in FIG. 4B may be used. As explained for FIG. 4C, the number of diodes in each diode chain may be depend on the voltages involved and leakage requirements.

In the embodiment of FIG. 4D, Bias 1 is equal to (VDD−VIO)/2, and Bias 2 is equal to (VIO−VSS)/2 where VIO is the voltage at IO terminal 12. Also here, for example variations +/−10% are acceptable.

FIG. 4E shows a variation of the embodiment of FIG. 4D. In FIG. 4E, in addition to the elements discussed with respect to FIG. 4D, a first capacitor 44A is coupled between first supply rail 10 and a node between diode chains 43C, 43D where Bias 2 is provided, and a second capacitor 44B is provided between second supply rail 11 and a node between diode chains 43A, 43B where Bias 1 is provided. Capacitors 44A, 44B may enhance the ESD behaviour of the second stage, as the capacitors may help to faster build up bias voltages for turning on the electrostatic discharge protection device 20. Otherwise, the explanations with respect to FIG. 4D also apply to FIG. 4E, including the resulting bias voltages Bias 1, Bias 2 and variations like using resistive or capacitive dividers instead of diode chain based dividers.

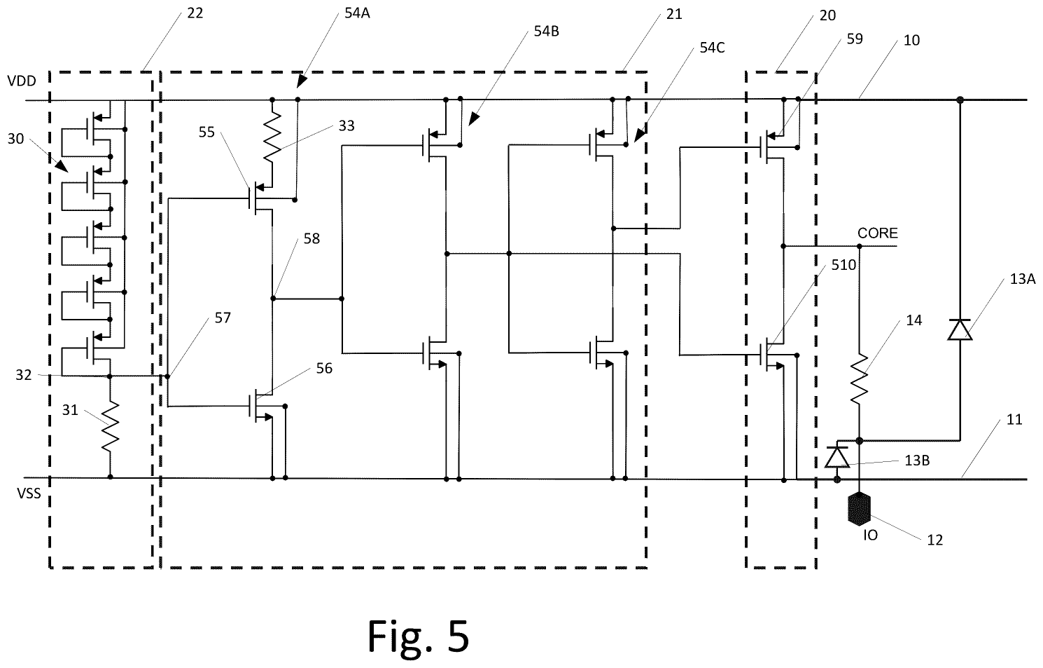

FIG. 5 illustrates a device according to a further embodiment. The embodiment of FIG. 5 is a variation of the embodiment of FIG. 3. While in FIG. 3 stacked transistors are used for inverter stages and for the electrostatic discharge protection device 20, in FIG. 5 single transistors are used for inverter stages 54A, 54B and 54C of amplifier circuit 21 and in electrostatic discharge protection device 20. In particular, each inverter stage 54A, 54B and 54C comprises a PMOS transistor 55 and an NMOS transistor 56, the gate terminals of which are coupled to an input node 57 of the respective inverter, and an output node 58 of the respective inverter being between transistors 55, 56. Resistor 33 already explained with respect to FIG. 3 again is provided only in inverter stage 54A, but not in inverter stages 54B and 54C.

Electrostatic discharge protection device 20 comprises a PMOS transistor 59, the gate of which is coupled to an output of inverter stage 54C (similar to PMOS transistor 39A of FIG. 3), and an NMOS transistor 510 has its gate terminal coupled to an output of inverter stage 54B (similar to NMOS transistor 310B of FIG. 3). Apart from not using stacked transistors, operation of the device of FIG. 5 corresponds to the one explained for FIG. 3. The device of FIG. 5 may be used in technologies where the single transistors (as opposed to stacked transistors) can withstand the voltages involved.

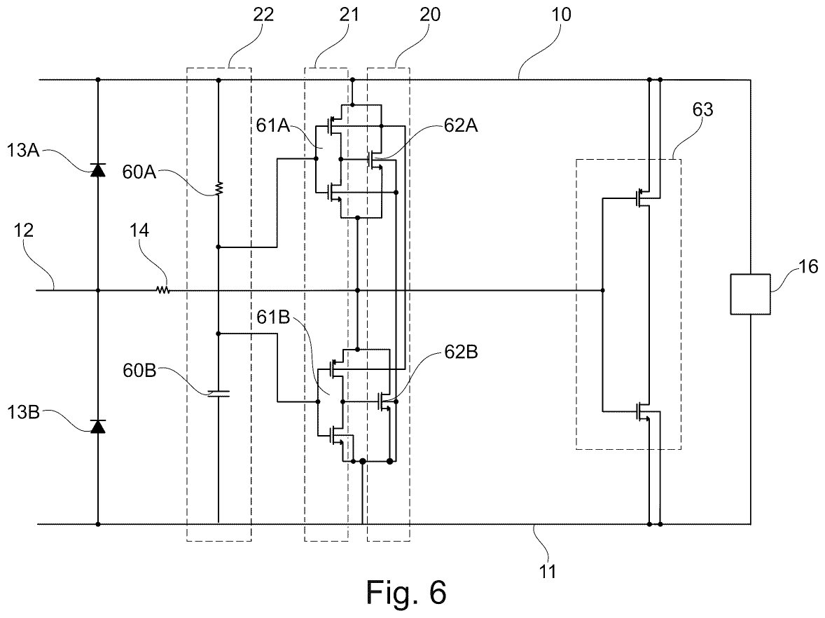

FIG. 6 illustrates a device according to a further embodiment. The device of FIG. 6 differs from the previous embodiments regarding the implementations of detection circuit 22, amplifier circuit 21 and ESD protection device 20, as will be explained below.

Furthermore, in FIG. 6 the core circuit is represented by a simple input stage 63.

Detection circuit 22 in the device of FIG. 6, in contrast to the previous embodiments, is not based on a divider circuit, but includes an RC filter including a resistor 60A coupled between first supply rail 10 and IO terminal 12 (via resistor 14), and a capacitor 60B coupled between IO terminal 12 (via resistor 14) and second supply rail 11. A resistance value of resistor 60A and a capacitance value of capacitor 60B are selected such that a detection signal ultimately activating ESD protection device 20 is generated when a voltage rise at IO terminal 12 has a time constant corresponding to typical time constants of a voltage rise of an ESD event. The use of RC circuits to detect ESD events per se is known to the skilled person, however, in case of FIG. 6 an ESD event at IO terminal 12 is detected by an RC circuit coupled between first supply rail 10 and second supply rail 11, thus detecting the change of supply voltage caused by the ESD event via diode 13A and/or diode 13B.

It should be noted that the RC-based detection circuit 22 may also be used in the previous embodiments instead of the divider-based detection circuits.

The detection signal in case of FIG. 6 is generated at nodes between resistor 60A and capacitor 60B. The amplification circuit 21 in the embodiment of FIG. 6 includes a single stage, with a first inverter 61A and a second inverter 61B, each including a PMOS transistor and an NMOS transistor. In other embodiments, a plurality of inverter stages as in FIG. 5 may be used, and/or stacked transistors as in FIG. 3 may be used. Conversely, in yet other embodiments, amplifier circuit 21 of FIG. 6 may for example also be used in the embodiment of FIG. 3 or 5.

In FIG. 6, the ESD protection device 20, similar to ESD protection device of FIG. 5, comprises an NMOS transistor 62A and an NMOS transistor 62B. A gate terminal of NMOS transistor 62A is coupled to an output of inverter 61A and a gate terminal of NMOS transistor 62B is coupled to an output of inverter 61B. Therefore, also in FIG. 6 in case of an ESD event both transistors 62A or 62B are switched on. Also in FIG. 6, in ESD protection device 20 instead of single transistors stacked transistors can be used, as explained with reference to FIG. 3.

Some embodiments are defined by the following examples:
Example 1. A device, comprising: a first supply rail, a second supply rail, an input/output terminal, an electrostatic discharge protection device comprising at least two stacked transistors coupled between the input/output terminal and one of the first supply rail and the second supply rail, a trigger circuit coupled to the first supply rail and the second supply rail and configured to detect an electrostatic discharge event at the input/output terminal based on at least one of a voltage at the first supply rail and a voltage at the second supply rail and to switch on the electrostatic discharge protection device in response to detecting the electrostatic discharge event.
Example 2. The device of example 1, wherein the at least two stacked transistors comprise a first transistor controlled by the trigger circuit and a second transistor, and wherein the device further comprises a bias circuit configured to bias a control terminal of the second transistor to a predefined voltage value.
Example 3. The device of example 2, wherein the predefined voltage value is between 40% and 60% of a mean value of a first voltage at the first supply rail and a second voltage at the second supply rail.
Example 4. The device of any one of examples 1 to 3, wherein the electrostatic discharge protection device comprises at least two further stacked transistors coupled between the input/output terminal and the other one of the first supply rail and the second supply rail.
Example 5. The device of example 4 and of example 2, wherein the at least two further stacked transistors comprise a first further transistor controlled by the trigger circuit and a second further transistor, and wherein the bias circuit is further configured to bias a control terminal of the second further transistor to a further predefined voltage value.
Example 6. The device of example 5, wherein the further predefined voltage value is equal to the predefined voltage value.
Example 7. The device of example 5, wherein the at least two stacked transistors are coupled between the input/output terminal and the first supply rail, wherein the at least two further stacked transistors are coupled between the input/output terminal and the second supply rail, wherein the predefined voltage value is between 40% and 60% of a mean value of a first voltage at the first supply rail and a third voltage at the input/output terminal, and the further predefined voltage value is between 40% and 60% of a mean value of a second voltage at the second supply rail and the third voltage at the input/output terminal.
Example 8. The device of any one of examples 1 to 7, further comprising a first electrostatic discharge protection element coupled between a first node coupled to the input/output terminal and the first supply rail and a second electrostatic discharge protection element coupled between the first node and the second supply rail, wherein the electrostatic discharge protection device is coupled between a second node coupled to the input/output terminal and the one of the first supply rail and the second supply rail, wherein the first node is between the input/output terminal and the second node.
Example 9. The device of example 8, further comprising a current limiting element coupled between the first node and the second node.
Example 10. The device of any one of examples 1 to 9, wherein the trigger circuit comprises a detection circuit configured to generate a detection signal indicative of the electrostatic discharge event.
Example 11. The device of example 10, wherein the detection circuit comprises a voltage divider circuit coupled between the first and second supply rails, wherein an output of the voltage divider circuit is configured to provide the detection signal.
Example 12. The device of example 11, wherein the voltage divider circuit comprises at least one diode in series with a resistor, wherein the output of the voltage divider circuit is at a node between the at least one diode and the resistor.
Example 13. The device of example 10, wherein the detection circuit comprises an RC filter circuit coupled between the first and second supply rails, wherein an output of the RC filter circuit is configured to provide the detection signal.
Example 14. The device of any one of examples 10 to 11, further comprising an amplifier circuit configured to amplify the detection signal to generate a control signal for the electrostatic discharge protection device.
Example 15. The device of example 14, wherein the amplifier circuit comprises one or more inverter stages.
Example 16. The device of example 15, wherein each inverter stage comprises a first pair of stacked transistors coupled between the first supply rail and an output node of the respective inverter stage and a second pair of stacked transistors coupled between the output node of the respective inverter stage and the second supply rail.
Example 17. The device of example 16 and of example 5, wherein the at least two stacked transistors are coupled between the input/output terminal and the first supply rail, wherein the at least two further stacked transistors are coupled between the input/output terminal and the second supply rail, wherein a first transistor of the first pair and a first transistor of the second pair are coupled to an input node of the respective inverter stage, wherein the bias circuit is configured to bias a control terminal of a second transistor of the first pair to the predefined voltage and to bias a control terminal of a second transistor of the second pair to the further predefined voltage.
Example 18. A device, comprising: a first supply rail, a second supply rail, an input/output terminal, an electrostatic discharge protection switch coupled between the input/output terminal and one of the first supply rail and the second supply rail, a detection circuit coupled to the first supply rail and the second supply rail and configured to detect an electrostatic discharge event at the input/output terminal based on at least one of a voltage at the first supply rail and a voltage at the second supply rail and to generate a detection signal in response to detecting the electrostatic discharge event, and an amplifier circuit configured to amplify the detection signal to generate a control signal for the electrostatic discharge protection switch.
Example 19. The device of example 18, wherein the amplifier circuit comprises one or more inverter stages, wherein each inverter stage comprises a first pair of stacked transistors coupled between the first supply rail and an output node of the respective inverter stage, and a second pair of stacked transistors coupled between the output node of the respective inverter stage and the second supply rail.
Example 20. The device of example 19, further comprising a bias circuit, wherein a first transistor of the first pair and a first transistor of the second pair are coupled to an input node of the respective inverter stage, wherein the bias circuit is configured to bias a control terminal of a second transistor of the first pair to a first predefined voltage and to bias a control terminal of a second transistor of the second pair to a second predefined voltage (Bias 2).
Example 21. The device of example 20, wherein the first predefined voltage value and the second predefined voltage value are each between 40% and 60% of a mean value of a first voltage at the first supply rail and a second voltage at the second supply rail.
Example 22. The device of example 21, wherein the first predefined voltage value is equal to the second predefined voltage value.
Example 23. The device of example 20, wherein the first predefined voltage value is between 40% and 60% of a mean value of a first voltage at the first supply rail and a third voltage at the input/output terminal, and the second predefined voltage value is between 40% and 60% of a mean value of a second voltage at the second supply rail and the third voltage at the input/output terminal.
Example 24. The device of any one of examples 18 to 23, further comprising a first electrostatic discharge protection element coupled between a first node coupled to the input/output terminal and the first supply rail and a second electrostatic discharge protection element coupled between the first node and the second supply rail, wherein the electrostatic discharge protection switch is coupled between a second node coupled to the input/output terminal and the one of the first supply rail and the second supply rail, wherein the first node is between the input/output terminal and the second node.
Example 25. The device of example 24, further comprising a current limiting element coupled between the first node and the second node.
Example 26. The device of any one of examples 18 to 25, wherein the detection circuit comprises a voltage divider circuit coupled between the first and second supply rails, wherein an output of the voltage divider circuit is configured to provide the detection signal.
Example 27. The device of example 26, wherein the voltage divider circuit comprises at least one diode in series with a resistor, wherein the output of the voltage divider circuit is at a node between the at least one diode and the resistor.
Example 28. The device of any one of examples 18 to 24, wherein the detection circuit comprises an RC filter circuit coupled between the first and second supply rails, wherein an output of the RC filter circuit is configured to provide the detection signal.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A device, comprising:
a first supply rail;
a second supply rail;
an input/output terminal;
an electrostatic discharge protection device comprising at least two stacked transistors coupled between the input/output terminal and a first one of the first supply rail or the second supply rail; and
a trigger circuit coupled to the first supply rail and the second supply rail and configured to:
detect an electrostatic discharge event at the input/output terminal based on a voltage of the first supply rail or a voltage of the second supply rail, and
switch on the electrostatic discharge protection device in response to detecting the electrostatic discharge event.

2. The device of claim 1, wherein:
the at least two stacked transistors comprise a first transistor controlled by the trigger circuit and a second transistor; and
the device further comprises a bias circuit configured to bias a control terminal of the second transistor to a predefined voltage value.

3. The device of claim 2, wherein the predefined voltage value is between 40% and 60% of a mean value of a first voltage of the first supply rail and a second voltage of the second supply rail.

4. The device of claim 1, wherein the electrostatic discharge protection device comprises at least two further stacked transistors coupled between the input/output terminal and a second one of the first supply rail or the second supply rail.

5. The device of claim 4, wherein:
the at least two stacked transistors comprise a first transistor controlled by the trigger circuit and a second transistor;
the device further comprises a bias circuit configured to bias a control terminal of the second transistor to a predefined voltage value;
the at least two further stacked transistors comprise a first further transistor controlled by the trigger circuit and a second further transistor; and
the bias circuit is further configured to bias a control terminal of the second further transistor to a further predefined voltage value.

6. The device of claim 5, wherein the further predefined voltage value is equal to the predefined voltage value.

7. The device of claim 5, wherein:
the at least two stacked transistors are coupled between the input/output terminal and the first supply rail;
the at least two further stacked transistors are coupled between the input/output terminal and the second supply rail;
the predefined voltage value is between 40% and 60% of a mean value of a first voltage of the first supply rail and a third voltage of the input/output terminal; and
the further predefined voltage value is between 40% and 60% of a mean value of a second voltage of the second supply rail and the third voltage of the input/output terminal.

8. The device of claim 1, further comprising:
a first electrostatic discharge protection element coupled between a first node coupled to the input/output terminal and the first supply rail; and
a second electrostatic discharge protection element coupled between the first node and the second supply rail, wherein
the electrostatic discharge protection device is coupled between a second node coupled to the input/output terminal and the one of the first supply rail or the second supply rail, and
the first node is between the input/output terminal and the second node.

9. The device of claim 8, further comprising a current limiting element coupled between the first node and the second node.

10. The device of claim 1, wherein the trigger circuit comprises a detection circuit configured to generate a detection signal indicative of the electrostatic discharge event.

11. The device of claim 10, wherein the detection circuit comprises a voltage divider circuit coupled between the first and second supply rails, wherein an output of the voltage divider circuit is configured to provide the detection signal.

12. The device of claim 11, wherein the voltage divider circuit comprises at least one diode in series with a resistor, wherein the output of the voltage divider circuit is at a node between the at least one diode and the resistor.

13. The device of claim 10, wherein the detection circuit comprises an RC filter circuit coupled between the first and second supply rails, wherein an output of the RC filter circuit is configured to provide the detection signal.

14. The device of claim 10, further comprising an amplifier circuit configured to amplify the detection signal to generate a control signal for the electrostatic discharge protection device.

15. The device of claim 14, wherein the amplifier circuit comprises one or more inverter stages.

16. The device of claim 15, wherein each inverter stage comprises:
a first pair of stacked transistors coupled between the first supply rail and an output node of the respective inverter stage; and
a second pair of stacked transistors coupled between the output node of the respective inverter stage and the second supply rail.

17. The device of claim 16, wherein:
the at least two stacked transistors comprise a first transistor controlled by the trigger circuit and a second transistor;
the device further comprises a bias circuit configured to bias a control terminal of the second transistor to a predefined voltage value;
the at least two further stacked transistors comprise a first further transistor controlled by the trigger circuit and a second further transistor;
the bias circuit is further configured to bias a control terminal of the second further transistor to a further predefined voltage value;
the at least two stacked transistors are coupled between the input/output terminal and the first supply rail;
the at least two further stacked transistors are coupled between the input/output terminal and the second supply rail;
a first transistor of the first pair and a first transistor of the second pair are coupled to an input node of the respective inverter stage; and
the bias circuit is configured to:
bias a control terminal of a second transistor of the first pair to the predefined voltage value, and
bias a control terminal of a second transistor of the second pair to the further predefined voltage value.

18. A device, comprising:
a first supply rail;
a second supply rail;
an input/output terminal;
an electrostatic discharge protection switch coupled between the input/output terminal and one of the first supply rail or the second supply rail;
a detection circuit coupled to the first supply rail and the second supply rail and configured to:
detect an electrostatic discharge event at the input/output terminal based a voltage of the first supply rail or a voltage at the second supply rail, and
generate a detection signal in response to detecting the electrostatic discharge event; and
an amplifier circuit configured to amplify the detection signal to generate a control signal for the electrostatic discharge protection switch.

19. The device of claim 18, wherein the amplifier circuit comprises one or more inverter stages, wherein each inverter stage comprises:
a first pair of stacked transistors coupled between the first supply rail and an output node of the respective inverter stage; and
a second pair of stacked transistors coupled between the output node of the respective inverter stage and the second supply rail.

20. The device of claim 19, further comprising a bias circuit, wherein:
a first transistor of the first pair and a first transistor of the second pair are coupled to an input node of the respective inverter stage; and
the bias circuit is configured to:
bias a control terminal of a second transistor of the first pair to a first predefined voltage, and
bias a control terminal of a second transistor of the second pair to a second predefined voltage.
